(19) United States
(12) Patent Application Publication
(10) Pub. No.: US 2016/0125938 A1
(43) Pub. Date: May 5, 2016

(54) PHASE CHANGE MEMORY WITH METASTABLE SET AND RESET STATES

(71) Applicant: International Business Machines Corporation, Armonk, NY (US)

(72) Inventors: Matthew J. BrightSky, Pound Ridge, NY (US); SangBum Kim, Yorktown Heights, NY (US); Wanki Kim, White Plains, NY (US); Chung H. Lam, Peekskill, NY (US)

(21) Appl. No.: 14/749,161

(22) Filed: Jun. 24, 2015

Related U.S. Application Data
(63) Continuation of application No. 14/533,495, filed on Nov. 5, 2014.

(51) Int. Cl. G11C 13/00; H01L 45/00

(52) U.S. Cl. CPC G11C 13/0004; G11C 13/0069; H01L 45/06; H01L 45/144; G11C 2013/0078

(57) ABSTRACT

A memory device that includes a phase change material. The phase change material is programmable to a metastable set state and metastable reset state. Furthermore, the phase change material includes an initial state with an initial electrical resistance between the set electrical resistance and the reset electrical resistance. The initial state is at a lower potential energy than the set state and the reset state. Thus, the electrical resistance of the phase change material programmed to the set state or the reset state drifts toward the initial electrical resistance over time. The memory device also includes a first electrode electrically coupled to a first area of the phase change material, and a second electrode electrically coupled to a second area of the phase change material.

### CROSS-REFERENCE TO RELATED APPLICATIONS

This application is a continuation of and claims priority under 35 U.S.C. §120 to U.S. patent application Ser. No. 14/533,495, filed Nov. 5, 2014, titled “PHASE CHANGE MEMORY WITH METASTABLE SET AND RESET STATES”, and incorporated herein by reference in its entirety.

### BACKGROUND

This invention relates to computer memory, and more particularly, phase change memory with metastable set and reset states.

There are two major groups in computer memory: non-volatile memory and volatile memory. Constant input of energy in order to retain information is not necessary in non-volatile memory but is required in the volatile memory. Examples of non-volatile memory devices are Read Only Memory (ROM), Flash Electrical Erasable Read Only Memory, Ferroelectric Random Access Memory, Magnetic Random Access Memory (MRAM), and Phase Change Memory (PCM); non-volatile memory devices being memory in which the state of the memory elements can be retained for days to decades without power consumption. Examples of volatile memory devices include Dynamic Random Access Memory (DRAM) and Static Random Access Memory (SRAM); where DRAM requires the memory element to be constantly refreshed while SRAM requires a constant supply of energy to maintain the state of the memory element.

The present invention is directed to phase change memory. In phase change memory, information is generally stored in materials that can be manipulated into different phases. Each of these phases exhibit different electrical properties which can be used for storing information. The amorphous and crystalline phases are typically two phases used for bit storage (1's and 0's) since they have detectable differences in electrical resistance. Specifically, the amorphous phase (also referred to as the reset state) has a higher resistance than the crystalline phase (also referred to as the set state).

Chalcogenides are a group of materials commonly utilized as phase change material. This group of materials contain a chalcogen (Periodic Table Group 16/VIA) and another element. Selenium (Se) and tellurium (Te) are the two most common semiconductors in the group used to produce a chalcogenide when creating a phase change memory cell. An example of this would be Ge₂Sb₂Te₅ (GST), SbTe, and In₂Se₃.

### BRIEF SUMMARY

Accordingly, one example aspect of the present invention is a memory device that includes a phase change material. The phase change material has an electrical resistance and is programmable to a set state and reset state. The set state has a set electrical resistance and reset state has a reset electrical resistance at least a factor of 10 greater than the set electrical resistance. Furthermore, the phase change material includes an initial state with an initial electrical resistance between the set electrical resistance and the reset electrical resistance. The initial state is at a lower potential energy than the set state and the reset state. Thus, the electrical resistance of the phase change material programmed to the set state or the reset state drifts toward the initial electrical resistance over time. The memory device also includes a first electrode electrically coupled to a first area of the phase change material, and a second electrode electrically coupled to a second area of the phase change material.

Another example aspect of the present invention is a memory device with a phase change material. The phase change material includes GeₓSb_{y}Te_{z} where a Ge atomic concentration x is within a range from 30% to 70%, a Sb atomic concentration y is within a range from 10% to 30%, and a Te atomic concentration z is within a range from 20% to 50%. The memory device also includes a first electrode electrically coupled to a first area of the phase change material, and a second electrode electrically coupled to a second area of the phase change material.

### BRIEF DESCRIPTION OF THE DRAWINGS

The subject matter which is regarded as the invention is particularly pointed out and distinctly claimed in the claims at the conclusion of the specification. The foregoing and other objects, features, and advantages of the invention are apparent from the following detailed description taken in conjunction with the accompanying drawings in which:

FIG. 1 shows an example of a computer readable memory device contemplated by the present invention.

FIG. 2 shows a memory device with phase change material electrically coupled to a programmer circuit, as contemplated by the present invention.

FIG. 3A illustrates a set resistance drift of a memory cell contemplated by the present invention after baking the memory device at 260° C. for 15 minutes.

FIG. 3B illustrates a reset resistance drift of a memory cell contemplated by the present invention after baking the memory device at 260° C. for 20 seconds.

FIG. 4 illustrates using different reset voltages to control Rᵣₑₛₑₜ drift speed, as contemplated by the present invention.

### DETAILED DESCRIPTION

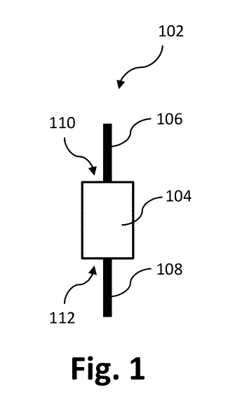

The present invention is described with reference to embodiments of the invention. Throughout the description of the invention reference is made to FIGS. 1-4. When referring to the figures, like structures and elements shown throughout are indicated with like reference numerals.

FIG. 1 shows an example of a computer readable memory device 102 contemplated by the present invention. The memory device 102 includes a phase change material 104 electrically coupled to a first electrode 106 at first area 110 of the phase change material 104 and a second electrode 108 at first area 112 of the phase change material 104.

The phase change material 104 is programmable to a set state and a reset state. The set state has a set electrical resistance. The reset state has a reset electrical resistance at least a factor of 10 greater than the set electrical resistance. The phase change material 104 includes an initial state with an initial electrical resistance between the set electrical resistance and the reset electrical resistance. Furthermore, the initial state is at a lower potential energy than the set state and the reset state such that the electrical resistance of the phase change material programmed to either the set state or the reset state drifts toward the initial electrical resistance over time. In other words, the set and reset states are metastable states, and the initial state is the ground state.

In one embodiment, the phase change material 104 is composed of GeₓSb_{y}Te_{z} where a Ge atomic concentration x is within a range from 30% to 70%, a Sb atomic concentration y is within a range from 10% to 30%, and a Te atomic concentration z is within a range from 20% to 50%. In a particular embodiment, the Ge atomic concentration x is greater than the Sb atomic concentration y, and the Te atomic concentration z. In an embodiment, the phase change material 104 includes a Ge atomic concentration of 48.1%, a Sb atomic concentration of 14.9%, a Te atomic concentration of 27.7%, and an N atomic concentration of 9.3%.

In one embodiment, the phase change material 104 is doped with a doping material. Particularly, the phase change material may doped with nitrogen, carbon, silicon, and/or oxygen. The dopants can change the memory device's characteristic operating voltages, resistances and/or drift speeds.

In one embodiment, the set electrical resistance of the set state is within a range of 10 kΩ and 100 kΩ, the reset electrical resistance of the reset state is within a range of 3 MΩ and 100 MΩ, and the initial electrical resistance of the initial state is within a range of 200 kΩ and 2 MΩ.

It is contemplated that the set resistance (Rset) of Ge-rich GST based PCM drifts up. Ge atoms have two different possible coordinations: tetrahedral and octahedral. Ge-rich GST has higher drift coefficient due to more gap states. Moreover, Ge-rich GST has residual amorphous Ge phase after set switching. Accordingly, Rset drifts up due to structural relaxation of residual amorphous phase at grain boundaries. While the fully crystalline set state is usually a stable state, the set state of Ge-rich GST has some residual amorphous Ge phase and is therefore a metastable state. Similarly, it is contemplated that the reset resistance (Rᵣₑₛₑₜ) of Ge-rich GST based PCM drifts down because of spontaneous crystallization. Therefore, initial state is a lower energy state than either the set state or the reset state. As a result, both Rₛₑₜ and Rᵣₑₛₑₜ of Ge-rich GST based PCM move toward a middle resistance after programming.

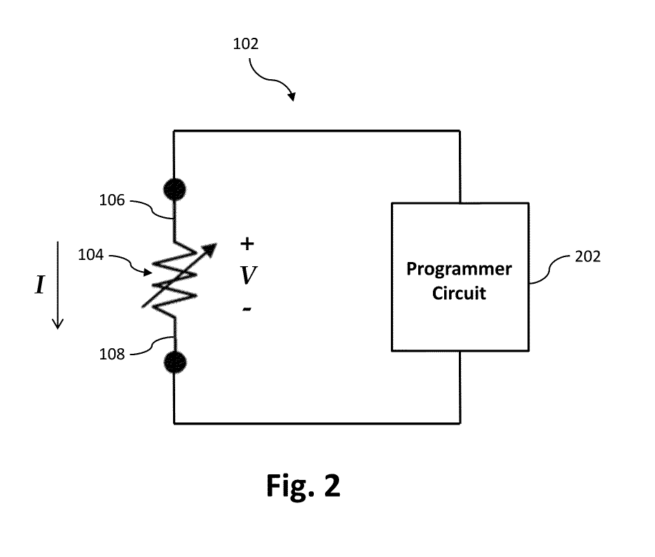

FIG. 2 shows the memory device 102 with phase change material 104 electrically coupled to a programmer circuit 202. The programmer circuit 202 is configured to apply a program voltage V (or a program current I) between the first electrode and the second electrode. Furthermore, the program voltage V or the program current I are inversely proportional to a drift speed of the phase change material toward the initial electrical resistance over time. Thus, by using different set and/or reset voltage, the Rset and/or Rreset drift speed can be controlled. In other words, the speed of forgetting can be controlled. For example, with a lower Vset and Vreset, the faster drift speed of Rₛₑₜ and Rᵣₑₛₑₜ (and the faster forgetting over time).

It is contemplated that the memory device 102 may be used in real-time self-learning applications. Real-time self-learning typically requires:

1. no pre-conditioning;

2. potentiation and depression of the synaptic device; and

3. forgetting over time.

The memory device addresses a real-time self-learning synaptic device based on phase change memory. No extra hardware or software is needed for the memory cell to forget over time. In other words, the two-terminal memory cell forgets stored information over time by itself.

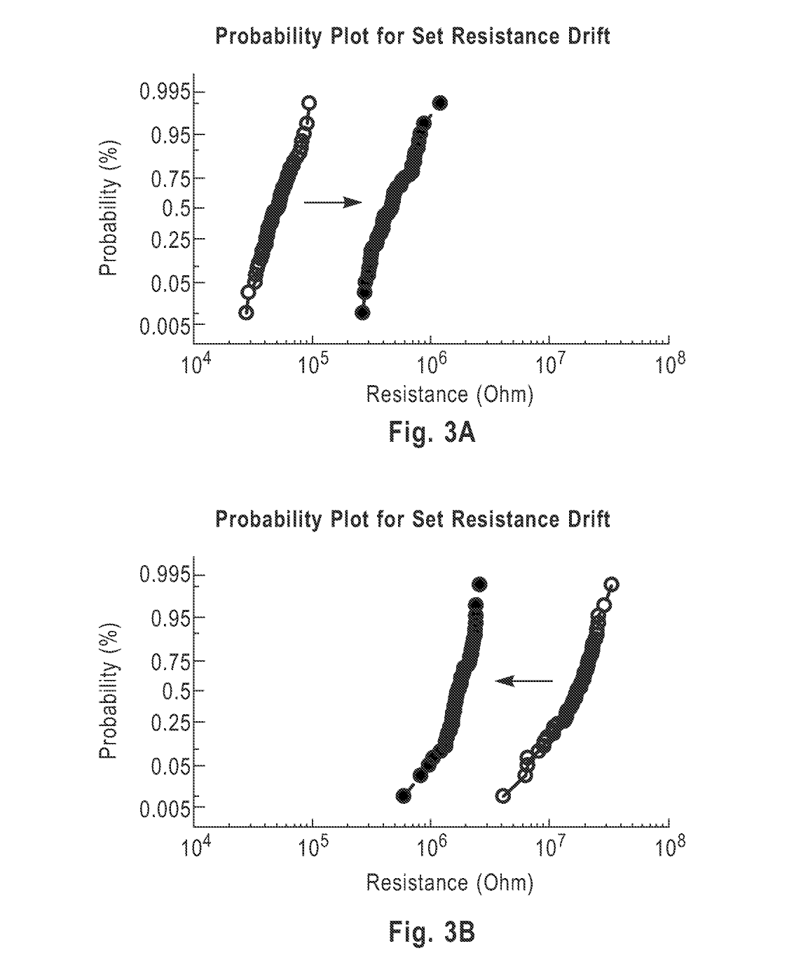

FIG. 3A illustrates a set resistance drift of the memory cell contemplated by the present invention after baking the memory device at 260° C. for 15 minutes. The high temperature bake accelerates the resistance change to simulate a long period of time passing. As shown, the set resistance, within the range of 10 kΩ to 100 kΩ drifts to an initial resistance within the range of 200 kΩ to 2 MΩ after bake.

FIG. 3B illustrates a reset resistance drift of the memory cell contemplated by the present invention after baking the memory device at 260° C. for 20 seconds. As shown, the reset resistance, within the range of 3 MΩ to 100 MΩ drifts to the initial resistance within the range of 200 kΩ to 2 MΩ after bake. It is noted that the distributions of the set, reset and initial resistances are Gaussian.

In one embodiment, the memory device may be used as a real-time self-learning synaptic device that forgets over time. The memory device can learn relevant information by set switching and can also learn irrelevant information by reset switching. If one PCM cell has not been learned for a long time since last learning process, the cell goes back to original state (initial resistance) since resistance of memory cell drifts to middle after the set or reset switching. Thus, the memory cell forgets over time like actual synapses do in the human brain. No extra hardware or software is needed for forgetting over time.

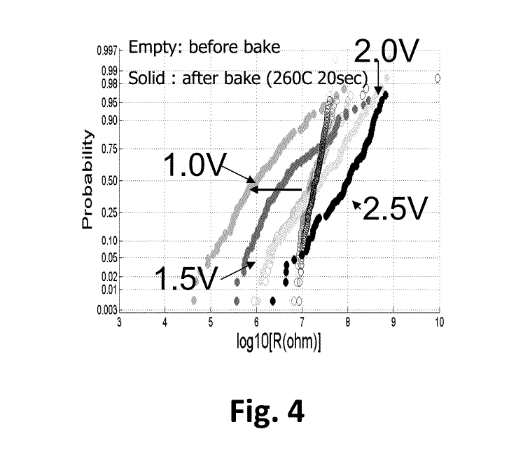

FIG. 4 illustrates using different reset voltages to control Rᵣₑₛₑₜ drift speed (i.e., speed of forgetting). For example, by using lower Vᵣₑₛₑₜ voltages, the drift speed of Rᵣₑₛₑₜ increases. This corresponds to faster forgetting over time.

The descriptions of the various embodiments of the present invention have been presented for purposes of illustration, but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

1. A memory device comprising:
a phase change material having an electrical resistance and programmable to a set state having a set electrical resistance and reset state having a reset electrical resistance at least a factor of 10 greater than the set electrical resistance, the phase change material including an initial state having an initial electrical resistance between the set electrical resistance and the reset electrical resistance, the initial state is at a lower potential energy than the set state and the reset state such that the electrical resistance of the phase change material programmed to the set state or the reset state drifts toward the initial electrical resistance over time;
a first electrode electrically coupled to a first area of the phase change material; and
a second electrode electrically coupled to a second area of the phase change material.

2. The memory device of claim 1, wherein
the phase change material includes GeₓSb_{y}Te_{z}, where a Ge atomic concentration x is within a range from 30% to 70%, a Sb atomic concentration y is within a range from 10% to 30%, and a Te atomic concentration z is within a range from 20% to 50%.

3. The memory device of claim 2, wherein the Ge atomic concentration x is greater than the Sb atomic concentration y.

4. The memory device of claim 1, wherein the phase change material includes a Ge atomic concentration of 48.1%, a Sb atomic concentration of 14.9%, a Te atomic concentration of 27.7%, and an N atomic concentration of 9.3%.

5. The memory device of claim 1, wherein the phase change material is doped with nitrogen.

6. The memory device of claim 1, wherein the phase change material is doped with carbon.

7. The memory device of claim 1, wherein the phase change material is doped with silicon.

8. The memory device of claim 1, wherein the phase change material is doped with oxygen.

9. The memory device of claim 1, wherein the set electrical resistance is within a range of 10 kΩ) and 100 kΩ, the reset electrical resistance is within a range of 3 MΩ) and 100 MΩ, and the initial electrical resistance is within a range of 200 kΩ and 2 MΩ.

10. The memory device of claim 1, further comprising a programmer circuit configured to apply a program voltage or a program current between the first electrode and the second electrode, the program voltage or the program current being inversely proportional to a drift speed of the phase change material toward the initial electrical resistance over time.

11. A memory device comprising:
a phase change material having an electrical resistance and programmable to a set state having a set electrical resistance and reset state having a reset electrical resistance at least a factor of 10 greater than the set electrical resistance, the phase change material including an initial state having an initial electrical resistance between the set electrical resistance and the reset electrical resistance, the initial state is at a lower potential energy than the set state and the reset state;
a first electrode electrically coupled to a first area of the phase change material; and
a second electrode electrically coupled to a second area of the phase change material.

12. The memory device of claim 11, wherein the phase change material includes GeₓSb_{y}Te_{z} where a Ge atomic concentration x is within a range from 30% to 70%, a Sb atomic concentration y is within a range from 10% to 30%, and a Te atomic concentration z is within a range from 20% to 50%; and wherein the Ge atomic concentration x is greater than the Sb atomic concentration y and the Te atomic concentration z.

13. The memory device of claim 12, wherein the Ge atomic concentration x is greater than the Sb atomic concentration y.

14. The memory device of claim 11, wherein the phase change material includes a Ge atomic concentration of 48.1%, a Sb atomic concentration of 14.9%, a Te atomic concentration of 27.7%, and an N atomic concentration of 9.3%.

15. The memory device of claim 11, wherein the phase change material is doped with nitrogen.

16. The memory device of claim 11, wherein the phase change material is doped with carbon.

17. The memory device of claim 11, wherein the phase change material is doped with silicon.

18. The memory device of claim 11, wherein the electrical resistance of the phase change material programmed to the set state drifts toward the initial electrical resistance and the electrical resistance of the phase change material programmed to the reset state drifts toward the initial electrical resistance.

19. The memory device of claim 11, wherein the set electrical resistance is within a range of 10 kΩ) and 100 kΩ), the reset electrical resistance is within a range of 3 MΩ) and 100 MΩ, and the initial electrical resistance is within a range of 200 kΩ and 2 MΩ.

20. The memory device of claim 2, wherein the Ge atomic concentration x is greater than the Sb atomic concentration y and the Te atomic concentration z.
